(19) United States
(12) Patent Application Publication
(10) Pub. No.: US 2026/0190766 A1
(43) Pub. Date: Jul. 2, 2026

(54) DISPLAY DEVICE

(71) Applicant: LG ELECTRONICS INC., Seoul (KR)

(72) Inventors: Sungyul An, Seoul (KR); Jongyun Im, Seoul (KR); Doochan Cho, Seoul (KR); Junyoung Jeon, Seoul (KR)

(73) Assignee: LG ELECTRONICS INC., Seoul (KR)

(21) Appl. No.: 19/432,585

(22) Filed: Dec. 24, 2025

(30) Foreign Application Priority Data
Dec. 27, 2024 (KR) 10-2024-0198353

(51) Int. Cl. H10K 59/80; H10K 102/00

(52) U.S. Cl. CPC H10K 59/872; H10K 2102/311

(57) ABSTRACT

A display device including a flexible plate; a flexible display panel coupled to the flexible plate; a first side frame coupled to a rear first side of the flexible plate; a second side frame coupled to a rear second side of the flexible plate; a center frame coupled to the flexible plate between the first side frame and the second side frame; a first arm extending from the center frame to the first side frame, and rotatably coupled to the first side frame; a second arm extending from the center frame and the second side frame, and rotatably coupled to the second side frame; and a driving module on the center frame and configured to actuate slidable and moveable first and second rods in and out to slidably extend and retract the first arm and the second arm, respectively.

### CROSS-REFERENCE TO RELATED APPLICATION

This application claims priority to Korean Patent Application No. 10-2024-0198353, filed in the Republic of Korea on Dec. 27, 2024, the disclosure of which is incorporated herein by reference.

### BACKGROUND OF THE INVENTION

### Field of the Invention

The present disclosure relates to a display device. More particularly, the present disclosure relates to a display device capable of changing the curvature of a display panel.

### Description of the Related Art

As the information society develops, the demand for display devices is also increasing in various forms. In response to this, various display devices such as Liquid Crystal Display Device (LCD), Plasma Display Panel (PDP), Electroluminescent Display (ELD), Vacuum Fluorescent Display (VFD), and Organic Light Emitting Diode (OLED) have been researched and used in recent years.

Among them, an OLED panel can display images by depositing an organic layer that can emit light autonomously on a substrate on which a transparent electrode is formed. OLED panel is not only thin but also has flexible characteristics. Much research has been conducted on the structural characteristics of display device equipped with such an OLED panel.

### SUMMARY OF THE INVENTION

Accordingly, one object of the present disclosure to solve the above and other problems.

Another object of the present disclosure is to provide a structure that can freely change the curvature of a display panel.

Yet another object of the present disclosure is to provide a mechanism that can freely change the curvature of a display panel.

Another object of the present disclosure is to provide a structure for synchronizing the rotation of arms that bend or unfold a display panel.

Still another object of the present disclosure is to provide a structure for pushing or pulling arms while an actuator is lifted.

Another object of the present disclosure is to provide a structure for minimizing vibration and noise of an actuator.

In accordance with an aspect of the present disclosure, a display device can include a flexible display panel; a flexible plate which is positioned behind the display panel, and to which the display panel is coupled; a first side frame adjacent to a first side of the plate and coupled to a rear of the plate; a second side frame adjacent to a second side of the plate which is opposite to the first side of the plate and coupled to the rear of the plate; a first arm extending in a direction intersecting with the first side of the plate, and rotatably coupled to the first side frame; a second arm extending in a direction intersecting with the second side of the plate, and rotatably coupled to the second side frame; and a driving module positioned between the first arm and the second arm, and rotating the first arm and the second arm.

### BRIEF DESCRIPTION OF THE DRAWINGS

The above and other objects, features and advantages of the present invention will be more apparent from the following detailed description in conjunction with the accompanying drawings, in which:

FIGS. 1 to 22 are diagrams illustrating examples of a display device according to embodiments of the present disclosure.

### DETAILED DESCRIPTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another. When an element is referred to as being “coupled,” “fixed,” “mounted,” “connected,” “linked,” etc. to another element, there may be intervening elements present. When an element is referred to as being “directly coupled,” “directly fixed,” “directly mounted,” “directly connected,” “directly linked” etc. to another element, there are no intervening elements present.

A singular representation may include a plural representation unless context clearly indicates otherwise. In the present application, it should be understood that the terms “comprises, includes,” “has,” etc. specify the presence of features, numbers, steps, operations, elements, components, or combinations thereof described in the specification, but do not preclude the presence or addition of one or more other features, numbers, steps, operations, elements, components, or combinations thereof. The direction indications of up U, down D, left Le, right Ri, front F, and rear R shown in the drawings are only for the convenience of explanation, and the technical concepts disclosed in this specification are not limited thereby.

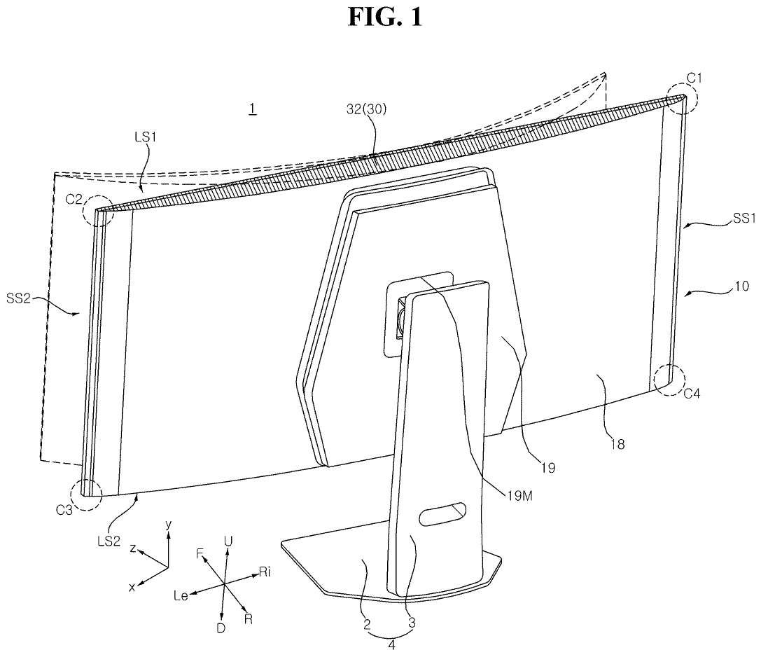

Referring to FIG. 1, a display device 1 can include a display 10 for displaying an image in a forward direction, and can be referred to as a display unit 10 or a display head 10. As shown, the display 10 can include a first long side LS1, a second long side LS2 opposite to the first long side LS1, a first short side SS1 adjacent to the first long side LS1 and the second long side LS2, and a second short side SS2 opposite to the first short side SS1. Also, the lengths of the first and second long sides LS1 and LS2 are illustrated as longer than the lengths of the first and second short sides SS1 and SS2, but the lengths of the first and second long sides LS1 and LS2 can be approximately the same as the lengths of the first and second short sides SS1 and SS2.

Further, the direction parallel to the long sides LS1, LS2 of the display 10 can be referred to as a left-right direction, and the direction parallel to the short sides SS1, SS2 of the display 10 can be referred to as an up-down direction. The direction perpendicular to the long sides LS1, LS2 and short sides SS1, SS2 of the display 10 can be referred to as a front-rear direction. In addition, the direction in which the display 10 displays an image can be referred to as a front (F, z), and the opposite direction can be referred to as a rear R. Also, the first short side SS1 side can be referred to as a right Ri, the second short side SS2 side can be referred to as a left (Le, x). In addition, the first long side LS1 side can be referred to as an upper side (U, y), and the second long side LS2 side can be referred to as a lower side D.

Further, the first long side LS1, the second long side LS2, the first short side SS1, and the second short side SS2 can be referred to as an edge of the display 10. Also, the point where the first long side LS1, the second long side LS2, the first short side SS1, and the second short side SS2 meet each other can be referred to as a corner.

A point where the first short side SS1 and the first long side LS1 meet can also be referred to as a first corner C1, and a point where the first long side LS1 and the second short side SS2 meet can be referred to as a second corner C2. In addition, a point where the second short side SS2 and the second long side LS2 meet can be referred to as a third corner C3, and a point where the second long side LS2 and the first short side SS1 meet can be referred to as a fourth corner C4.

In addition, a stand 2 of the display device 1 can be coupled to the display 10 and include a base 3 and a column 4. The base 3 can be placed on a table or a flat floor. Also, the column 4 can be extended from the base 3 and be coupled to the rear of the display 10. Accordingly, the stand 2 can support the display 10.

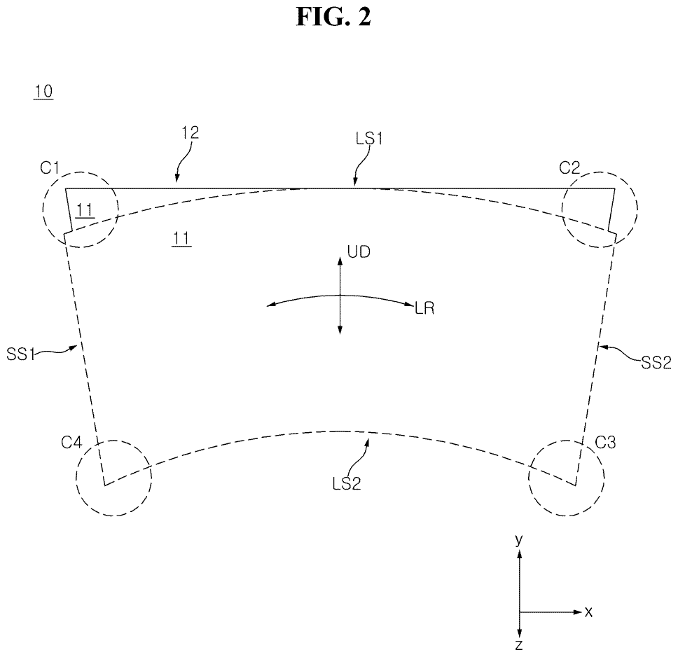

Referring to FIG. 2, a plate 12 of the display 10 can be flexible. For example, the plate 12 can be a metal plate. The plate 12 can be referred to as a flexible plate 12, a frame 12, or a base 12. FIG. 2 illustrates a display panel 11 of the display 10 can be coupled to the front of the plate 12. As shown in FIG. 2, the display panel 11 can be flexible. For example, the display panel 11 can be an Organic Light Emitting Diode (OLED) panel.

Further, the display panel 11 forms the front surface of the display 10, and displays an image. The display panel 11 can also divide an image into a plurality of pixels and display an image by adjusting the color, brightness, and saturation for each pixel. In addition, the display panel 11 can generate light corresponding to the color of red, green, or blue according to a control signal.

Also, the display 10 can have a variable curvature, and the left side and the right side of the display 10 can move in a forward direction. For example, when viewing an image from the front of the display 10, the display 10 can be concavely curved. The plate 12 can also be bent with the same curvature as the display panel 11. That is, the display panel 11 can be bent in correspondence with the curvature of the plate 12.

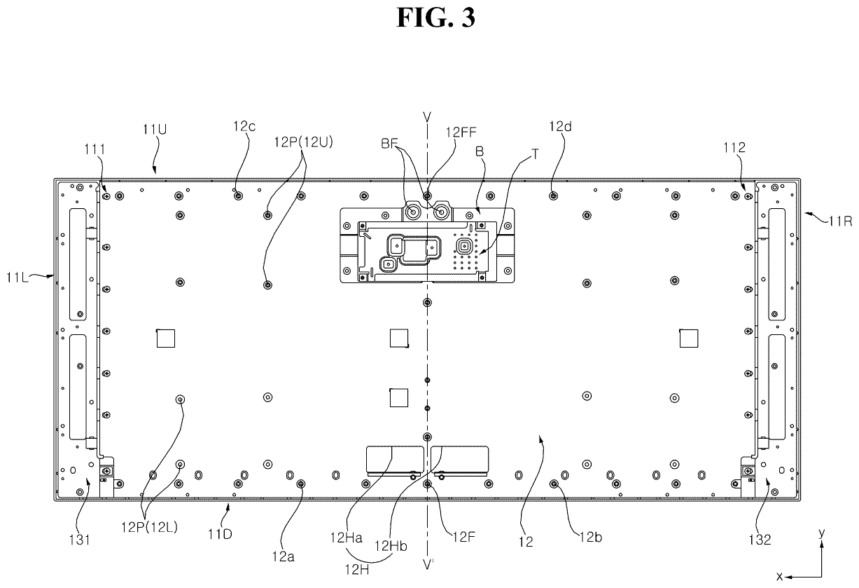

Referring to FIGS. 3-5, a source PCB 11a can be placed adjacent to the lower side 11D of the display panel 11, and can extend along the lower side 11D. In particular, the source PCB 11a can be positioned on the rear surface of the display panel 11, and can be electrically connected to the display panel 11 via a cable 11b such as Chip On Film (COF). The cables 11b can be arranged along the source PCB 11a.

Also, a first side plate 131 can be adjacent to the left side 11L of the display panel 11, and can extend along the left side 11L. The first side plate 131 can also be coupled to the rear surface of the display panel 11. A second side plate 132 can be adjacent to the right side 11R of the display panel 11, and can extend along the right side 11R. The second side plate 132 can be coupled to the rear surface of the display panel 11.

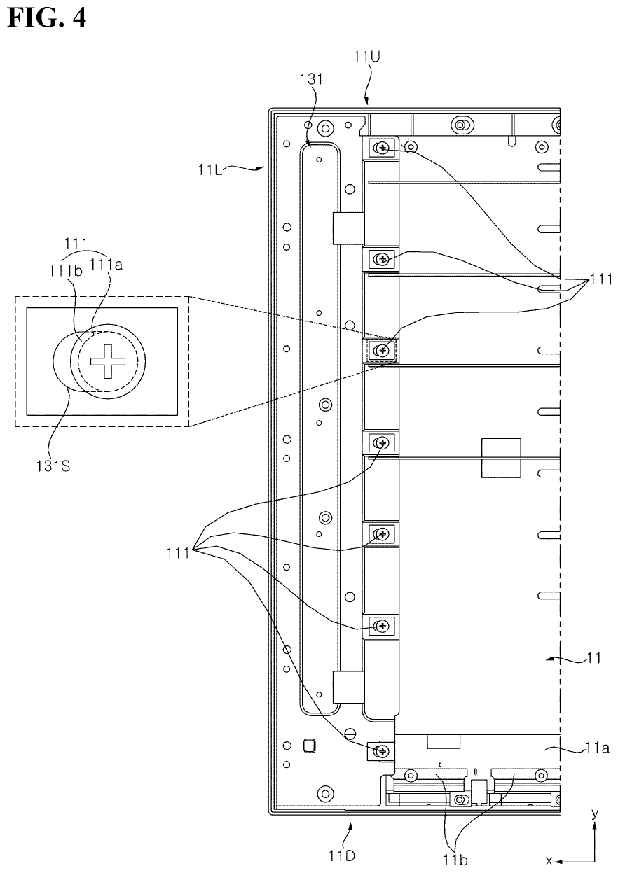

Referring to FIG. 4, a first side pin 111 can protrude from the rear surface of the display panel 11, and can be inserted into a first front slot 131S of the first side plate 131. In addition, the first side pins 111 can be arranged along the first side plate 131. Each of the first side pins 111 can be inserted into each of the first front slots 131S. Also, the width of the first front slot 131S can be larger than the diameter of a body 111a of the first side pin 111 penetrating the first front slot 131S. If the display panel 11 is flat, the first side pin 111 can be adjacent to the right distal end of the first front slot 131S.

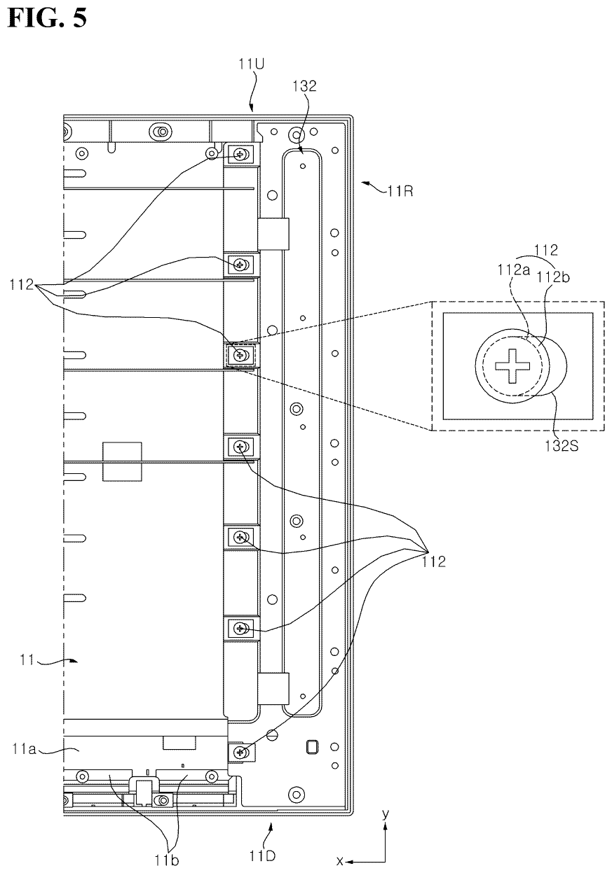

Referring to FIG. 5, a second side pin 112 can protrude from the rear surface of the display panel 11, and can be inserted into a second front slot 132S of the second side plate 132. The second side pins 112 can be arranged along the second side plate 132, and each of the second side pins 112 can be inserted into each of the second front slots 132S. In addition, the width of the second front slot 132S can be larger than the diameter of a body 112a of the second side pin 112 penetrating the second front slot 132S. When the display panel 11 is flat, the second side pin 112 can be adjacent to the left distal end of the second front slot 132S.

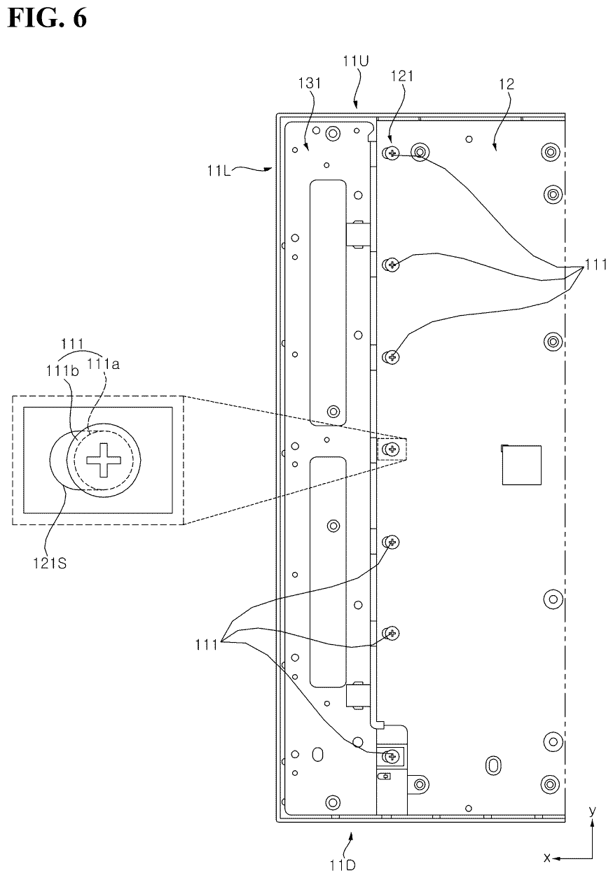

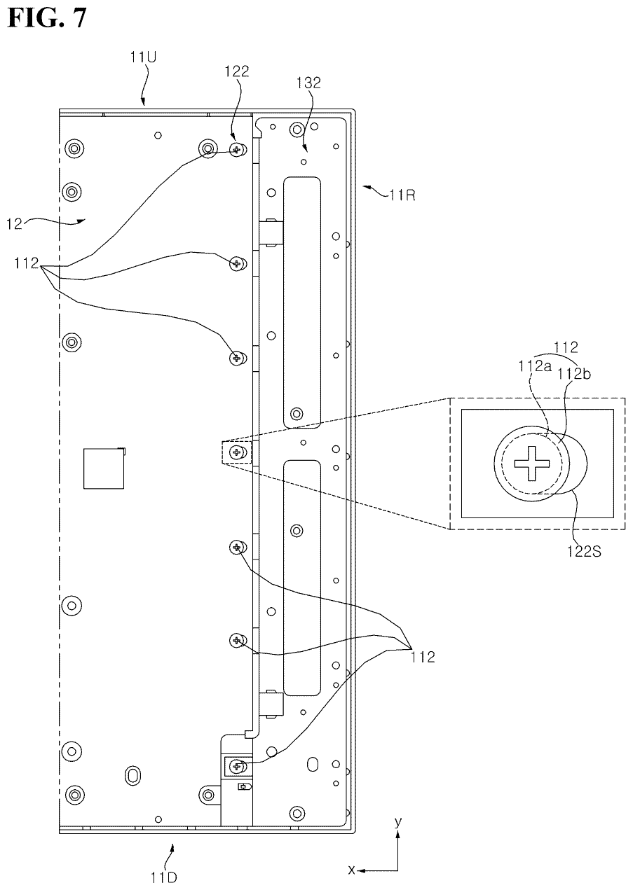

Referring to FIGS. 6 and 7, the plate 12 can be positioned between the first side plate 131 and the second side plate 132, and on the rear surface of the display panel 11. The plate 12 can thus cover the source PCB 11a and the cables 11b (see FIGS. 4 and 5) on the rear surface of the display panel 11.

Referring to FIG. 6, a first portion 121 of the plate 12 can cover a portion (see FIG. 4 of the first side plate 131 where the first front slots 131S are formed. The first side pin 111 can be inserted into a first rear slot 121S of the plate 12. In particular, the first rear slots 121S can be aligned with the first front slots 131S. Also, the width of the first rear slot 121S can be larger than the diameter of the body 111a of the first side pin 111 penetrating the first rear slot 121S. Thus, if the display panel 11 is flat, the first side pin 111 can be adjacent to the right distal end of the first rear slot 121S.

Referring to FIG. 7, a second portion 122 of the plate 12 can cover a portion (see FIG. 4) of the second side plate 132 where the second front slots 132S are formed. The second side pin 112 can be inserted into a second rear slot 122S of the plate 12. Also, the second rear slots 122S can be aligned with the second front slots 132S. The width of the second rear slot 122S can be larger than the diameter of the body 112a of the second side pin 112 penetrating the second rear slot 122S. Thus, if the display panel 11 is flat, the second side pin 112 can be adjacent to the left distal end of the second rear slot 122S.

In addition, the rear surface of the plate 12 can be engaged with a head 111b of the first side pin 111 and a head 112b of the second side pin 112. Accordingly, the plate 12 and the first and second side plates 131, 132 can be coupled to the display panel 11.

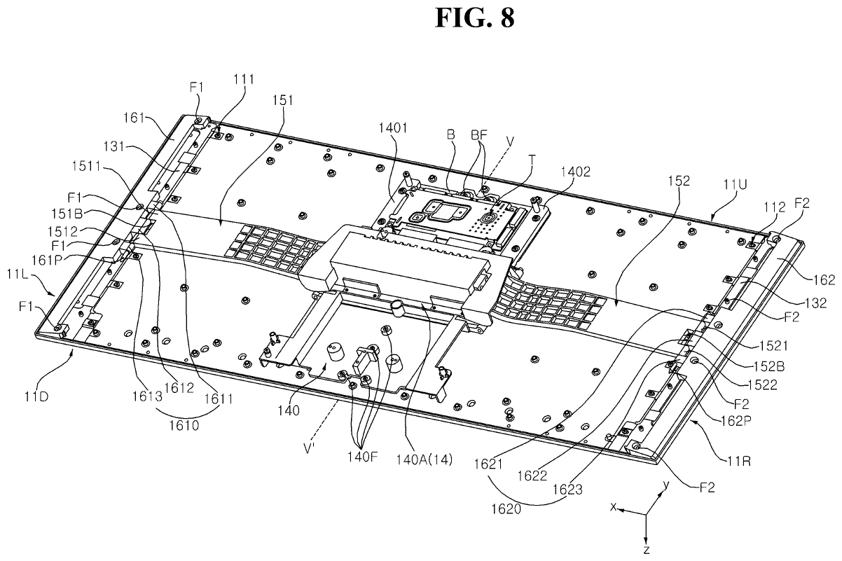

Referring to FIG. 8, a bracket B can be positioned on a vertical line VV′ passing through the central portion of the plate 12 and at the rear of the plate 12. Fastening members such as a screw can be fastened to the plate 12 by penetrating fixing parts BF (see FIG. 3) of the bracket B. In particular, the fixing parts BF of the bracket B can be positioned on the vertical line VV′ or on less than a certain distance Da from the vertical line VV′. In other words, the central portion of the bracket B can be fixed to the central portion of the plate 12.

A timing controller board T can also be coupled to the rear of the bracket B. As shown in FIG. 8, the timing controller board T can be adjacent to the central portion of the upper side of the plate 12. Alternatively, the timing controller board T can be adjacent to the central portion of the lower side of the plate 12. Also, a cable such as a flexible flat cable (FFC) can be electrically connected to the timing controller board T. The cable can be electrically connected to the source PCB 11a (see FIGS. 4 and 5) through the hole 12H (see FIG. 3) formed in the plate 12. Accordingly, the timing controller board T can provide a video signal to the display panel 11.

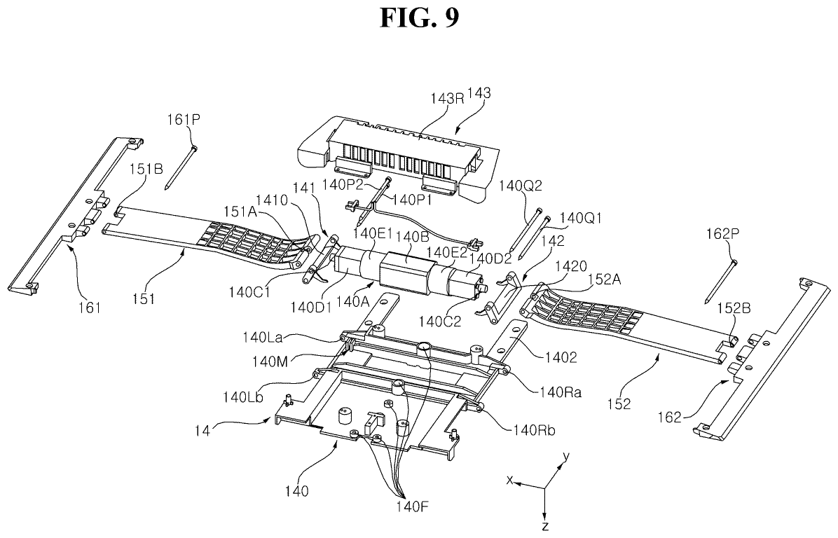

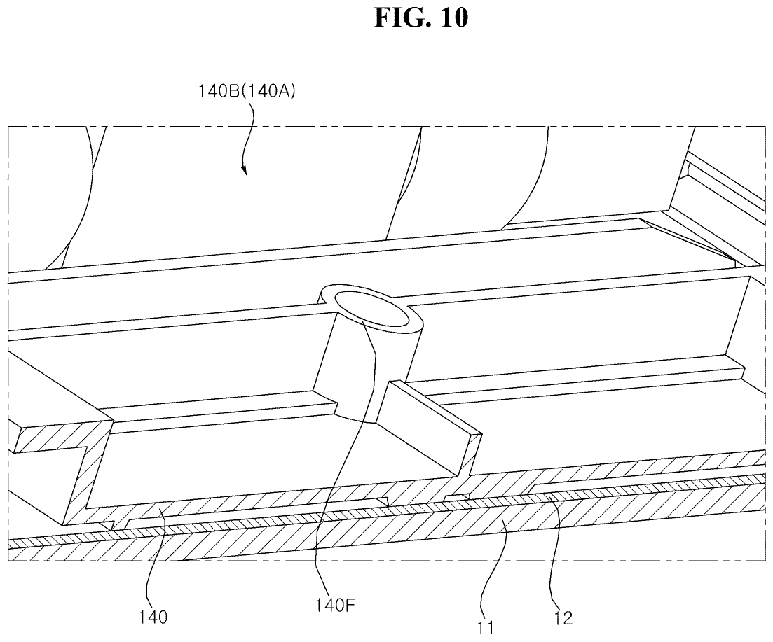

Referring to FIGS. 9 and 10, a driving module 14 can include a frame 140, an actuator 140A, a first link 141, and a second link 142. Further, the frame 140 can be positioned on a vertical line VV′ passing through the central portion of the plate 12 and at the rear of the plate 12. Fastening members such as screws can be fastened to the plate 12 by penetrating the fixing parts 140F of the frame 140. In addition, the fixing parts 140F can be positioned on the vertical line VV′ or on less than a certain distance Db from the vertical line VV′. In other words, the central portion of the frame 140 can be fixed to the central portion of the plate 12. FIG. 10 illustrates the outer part of the frame 140 can be spaced rearward from the plate 12, and the distance Ds between the outer part of the frame 140 and the plate 12 can increase as the plate 12 is bent. Meanwhile, FIG. 8 illustrates a first portion 1401 of the frame 140 can be fixed to the bracket B adjacent to the left side of the bracket B. Also, a second portion 1402 of the frame 140 can be fixed to the bracket B while being adjacent to the right side of the bracket B. As shown in FIG. 9, the actuator 140A can include a motor 140B, a first rod 140C1, and a second rod 140C2. The actuator 140A can be referred to as a linear actuator 140A.

In addition, the motor 140B can be an electric motor and the rotation direction, rotation angle, and rotation speed of the rotation shaft of the motor 140B can be adjusted. The motor 140B can also be a step motor. Further, the first rod 140C1 can be positioned in the first housing 140D1 on the left side of the motor 140B. In response to the driving of the motor 140B, the first rod 140C1 can move to the left and protrude from the first housing 140D1, or can move to the right and be inserted into the first housing 140D1. For example, the first rod 140C1 can be coupled to a first lead screw fixed to a first rotation shaft of the motor 140B, and can linearly reciprocate along the first lead screw. A first reducer 140E1 can be connected to the first rotation shaft of the motor 140B and reduce the rotation speed of the first rotation shaft of the motor 140B (i.e., increase the torque) and transmit to the first lead screw.

In addition, the second rod 140C2 can be positioned in the second housing 140D2 on the right side of the motor 140B. In response to the driving of the motor 140B, the second rod 140C2 can be moved to the right and protruded from the second housing 140D2, or can be moved to the left and inserted into the second housing 140D2. For example, the second rod 140C2 can be coupled to a second lead screw fixed to a second rotation shaft of the motor 140B and can linearly reciprocate along the second lead screw. Also, a second reducer 140E2 can be connected to the second rotation shaft of the motor 140B and reduce the rotation speed of the second rotation shaft of the motor 140B (i.e., increase the torque) and transmit to the second lead screw.

Accordingly, the actuator 140A can move the first and second rods 140C1, 140C2 by using a single motor 140B. Further, the moving directions of the first and second rods 140C1, 140C2 are opposite to each other. The moving distances of the first and second rods 140C1, 140C2 can be the same. For example, the first and second rotation shafts can be the same shaft.

As shown in FIG. 9, a first arm 151 can be extended lengthwise. The first arm 151 can be referred to as a first wing 151, and as shown, the first arm 151 can be extended from the first rod 140C1 toward the first side plate 131. Also, the width of the first arm 151 can be smaller than the length of the first arm 151. At least a portion of the first arm 151 can be curved. Intersecting ribs can also be formed on the rear surface of the first arm 151, and one side of the first arm 151 can be coupled to the first rod 140C1. In addition, the other side of the first arm 151 can be coupled to a first side frame 161. The first side frame 161 can extend in a direction intersecting with the first arm 151. The first side frame 161 can extend along the first side plate 131. The first side frame 161 can be coupled to the rear of the first side plate 131. Further, the first link 141 can be adjacent to the first rod 140C1. The first link 141 can connect the frame 140 and the first arm 151.

Similarly, a second arm 152 can be extended lengthwise. The second arm 152 can be referred to as a second wing 152. In particular, the second arm 152 can be extended from the second rod 140C2 toward the second side plate 132. Also, the width of the second arm 152 can be smaller than the length of the second arm 152. At least a portion of the second arm 152 can be curved. Intersecting ribs can be formed on the rear surface of the second arm 152, and one side of the second arm 152 can be coupled to the second rod 140C2. Further, the other side of the second arm 152 can be coupled to the second side frame 162. The second side frame 162 can extend in a direction intersecting with the second arm 152, and the second side frame 162 can extend along the second side plate 132. In addition, the second side frame 162 can be coupled to the rear of the second side plate 132, and the second link 142 can be adjacent to the second rod 140C2. The second link 142 can also connect the frame 140 and the second arm 152.

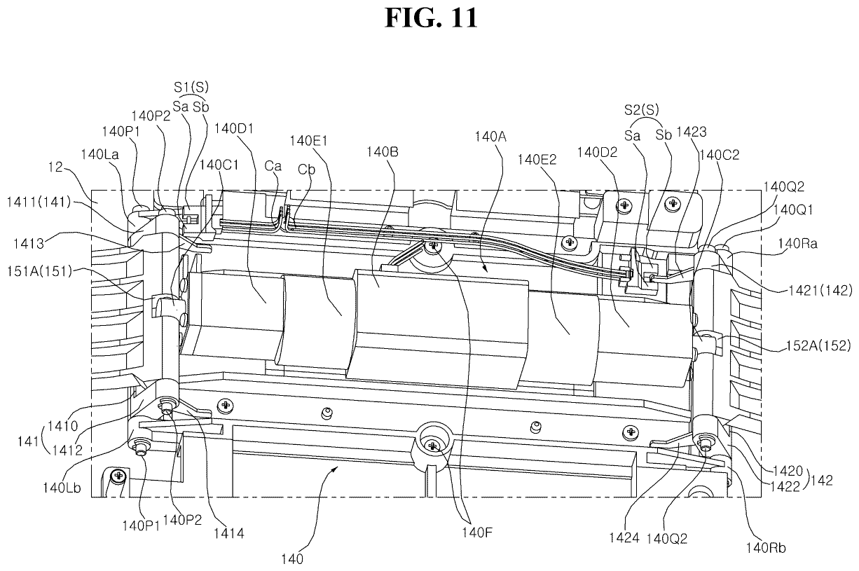

Referring to FIG. 11, the actuator 140A can be positioned at the rear of the frame 140, and the first rod 140C1 of the actuator 140A can be adjacent to the left side of the frame 140. Also, the second rod 140C2 of the actuator 140A can be adjacent to the right side of the frame 140.

As shown, a pair of first holders 140La, 140Lb can protrude from the left side of the frame 140, and can be spaced apart from each other along the left side. Also, the first link 141 can include a first link base 1410 and a pair of first wings 1411, 1412. The first link base 1410 can extend along the left side of the frame 140, and can be positioned between the pair of first holders 140La, 140Lb. In addition, a first front shaft 140P1 can penetrate the pair of first holders 140La, 140Lb and the first link base 1410. Further, the first link 141 can be coupled to the pair of first holders 140La, 140Lb so as to be advantageously rotatable (pivotable) about the first front shaft 140P1. The pair of first wings 1411, 1412, can protrude from the first link base 1410, and intersect with the first link base 1410. The first wing 1411 can be adjacent to one end of the first link base 1410, and the second wing 1412 can be adjacent to the other end of the first link base 1410.

In addition, one end of the first arm 151 can be positioned between the pair of first wings 1411, 1412. A first groove 151A can be formed at one end of the first arm 151. The first rod 130C1 can be inserted into the first groove 151A. A first rear shaft 140P2 can penetrate the pair of first wings 1411, 1412, the first arm 151, and the first rod 130C1. The first arm 151 can be coupled to the first link 141 so as to be rotatable about the first rear shaft 140P2. In addition, the first arm 151 can be coupled to the first rod 130C1 so as to be rotatable about the first rear shaft 140P2. In response to the movement of the first arm 151, the first arm 151 and the first link 141 can be rotated.

A pair of second holders 140Ra, 140Rb can also protrude from the right side of the frame 140, and can be spaced apart from each other along the right side. The second link 142 can include a second link base 1420 and a pair of second wings 1421, 1422. The second link base 1420 can extend along the right side of the frame 140, and can be positioned between the pair of second holders 140Ra, 140Rb. A second front shaft 140Q1 can penetrate the pair of second holders 140Ra, 140Rb and the second link base 1420. The second link 142 can also be coupled to the pair of second holders 140Ra, 140Rb so as to be advantageously rotatable (pivotable) about the second front shaft 140Q1. Further, the pair of second wings 1421, 1422 can protrude from the second link base 1420 and intersect with the second link base 1420. The second wing 1421 can be adjacent to one end of the second link base 1420, and the second wing 1422 can be adjacent to the other end of the second link base 1420.

One end of the second arm 152 can be positioned between the pair of second wings 1421, 1422. A second groove 152A can be formed in one end of the second arm 152. The second rod 130C2 can be inserted into the second groove 152A. A second rear shaft 140Q2 can penetrate the pair of second wings 1421, 1422, the second arm 152, and the second rod 130C2. The second arm 152 can be coupled to the second link 142 so as to be rotatable about the second rear shaft 140Q2. The second arm 152 can be coupled to the second rod 130C2 so as to be rotatable about the second rear shaft 140Q2. In response to the movement of the second arm 152, the second arm 152 and the second link 142 can be rotated.

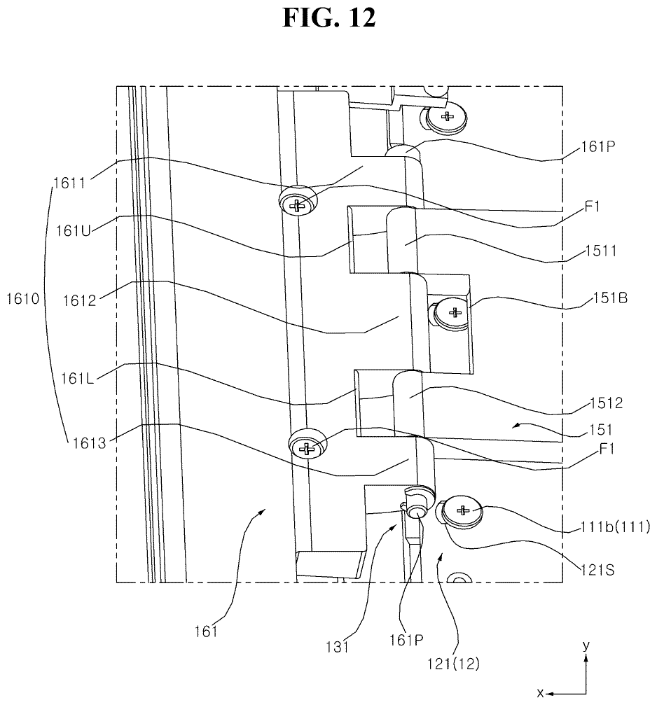

Referring to FIG. 12 together with FIG. 8, the first side frame 161 can extend along the left side 11L of the display panel 11, and the left side of the first side frame 161 can be adjacent to the left side 11L. Further, the second side frame 162 can extend along the right side 11R of the display panel 11, and the right side of the second side frame 162 can be adjacent to the right side 11R.

Also, a first fastening member F1 can fix the first side frame 161 to the first side plate 131. The first fastening members F1 can be arranged along the first side frame 161. The first fastening member F1 can be a screw. A second fastening member F2 can fix the second side frame 162 to the second side plate 132. In addition, the second fastening members F2 can be arranged along the second side frame 162 and can be a screw.

Also, a first holder 1610 can protrude from the first side frame 161 toward the first arm 151. In particular, the first holder 1610 can be formed at a central portion of the right side of the first side frame 161. As shown, the first holder 1610 can include parts 1611, 1612, 1613 that are spaced apart from each other. In particular, an upper groove 161U can be formed between an upper part 1611 and a middle part 1612, a lower groove 161L can be formed between the middle part 1612 and a lower part 1613, and a third groove 151B can be formed at the other end of the first arm 151. Further, the middle part 1612 can be inserted into the third groove 151B, and portions 1511, 1512 of the first arm 151 forming the third groove 151B can be inserted into the upper groove 161U and the lower groove 161L. Also, a first shaft 161P can penetrate the parts 1611, 1612, 1613 and the portions 1511, 1512 of the first arm 151. The first side frame 161 can be coupled to the first arm 151 so as to be rotatable about the first shaft 161P in response to the movement of the first arm 151.

Also, a second holder 1620 can protrude from the second side frame 162 toward the second arm 152. In particular, the second holder 1620 can be formed at a central portion of the left side of the second side frame 162. The second holder 1620 can include parts 1621, 1622, 1623 that are spaced apart from each other. As shown, an upper groove 162U can be formed between an upper part 1621 and a middle part 1622, a lower groove 162L can be formed between the middle part 1622 and a lower part 1623, and a fourth groove 152B can be formed at the other end of the second arm 152. Further, the middle part 1622 can be inserted into the fourth groove 152B, and portions 1521, 1522 of the second arm 152 forming the fourth groove 152B can be inserted into the upper groove 162U and the lower groove 162L. Also, a second shaft 162P can penetrate the parts 1621, 1622, 1623 and the portions 1521, 1522 of the second arm 152. The second side frame 162 can be coupled to the second arm 152 so as to be rotatable about the second shaft 162P in response to the movement of the second arm 152.

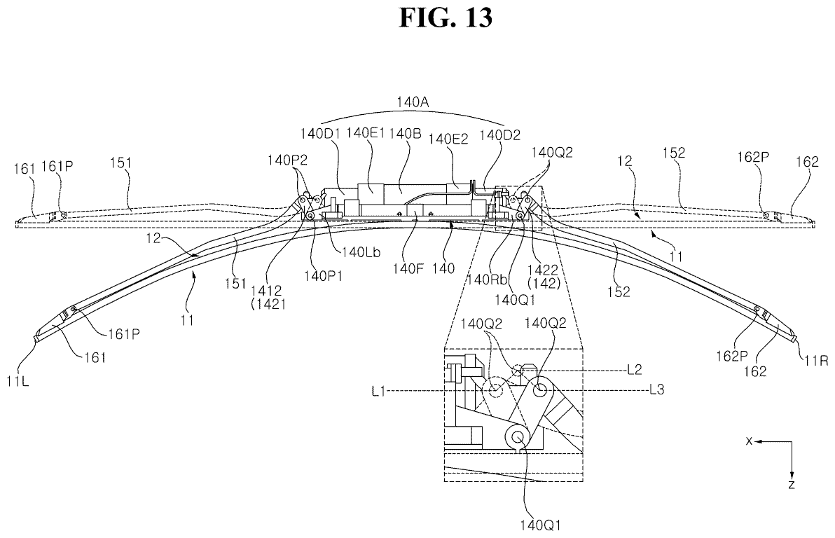

Referring to FIG. 13 together with FIG. 11, in response to the driving of the actuator 140A, the links 141, 142 and the arms 151, 152 can be rotated. The rotation shaft of the motor 140B of the actuator 140A can be rotated in a first rotation direction or a second rotation direction opposite to the first rotation direction. Also, the rods 140C1, 140C2 of the actuator 140A can push or pull the links 141, 142.

In response to the rotation of the rotation shaft of the motor 140B in the first rotation direction, the first rod 140C1 can move to the left, and the second rod 140C2 can move to the right. As shown, the first link 141 can be rotated counterclockwise by the first rod 140C1 moving to the left, and the first arm 151 connecting the first link 141 and the first side frame 161 can also be rotated counterclockwise. In addition, the second link 142 can be rotated clockwise by the second rod 140C2 moving to the right, and the second arm 152 connecting the second link 142 and the second side frame 162 can also be rotated clockwise. Accordingly, the left side 11L and the right side 11R of the display panel 11 can move in a forward direction. As the driving time of the motor 140B increases, the curvature of the display panel 11 can decrease.

In response to the rotation of the rotation shaft of the motor 140B in the second rotation direction, the first rod 140C1 can move to the right, and the second rod 140C2 can move to the left. As shown, the first link 141 can be rotated clockwise by the first rod 140C1 moving to the right, and the first arm 151 connecting the first link 141 and the first side frame 161 can also be rotated clockwise. In addition, the second link 142 can be rotated counterclockwise by the second rod 140C2 moving to the left, and the second arm 152 connecting the second link 142 and the second side frame 162 can also be rotated counterclockwise. Accordingly, the left side 11L and the right side 11R of the display panel 11 can move in a rearward direction. As the driving time of the motor 140B increases, the curvature of the display panel 11 can decrease.

Further, the links 141, 142 can pivot around the front shafts 140P1, 140Q1. The rear shafts 140P2, 140Q2 connecting the rods 140C1, 140C2 and the links 141, 142 can draw a circular trajectory with respect to the front shafts 140P1, 140Q1. When the display panel 11 and the plate 12 are flat, the rear shafts 140P2, 140Q2 and the rods 140C1, 140C2 can be positioned at a first level L1. When the display panel 11 and the plate 12 are bent to the maximum, the rear shafts 140P2, 140Q2 and the rods 140C1, 140C2 can be positioned at a second level L2. When the display panel 11 and the plate 12 are bent at a specific curvature that is smaller than the maximum curvature, the rear shafts 140P2, 140Q2 and the rods 140C1, 140C2 can be positioned at a third level L3. With respect to the frame 140, the third level L3 can be positioned higher than the first level L1 and the second level L2. With respect to the frame 140, the first level L1 and the second level L2 can be positioned at the same height. When the rear shafts 140P2, 140Q2 are positioned at the third level L3, the wings 1411, 1412, 1421, 1422 of the links 141, 142 can be perpendicular to the frame 140.

Accordingly, in response to the driving of the actuator 140A, the height of the actuator 140A having the rods 140C1, 140C2 connected to the rear shafts 140P2, 140Q2 can be changed. Specifically, as the position of the rods 140C1, 140C2 moves from the first level L1 to the second level L2, the actuator 140A can be moved in a rearward direction from the frame 140. As the position of the rods 140C1, 140C2 moves from the second level L2 to the third level L3, the actuator 140A can move toward the frame 140. The actuator 140A having the rods 140C1, 140C2 positioned at the second level L2 can be lifted from the frame 140. That is, the actuator 140A can be driven while being lifted, so that vibration and noise of the actuator 140A can be minimized.

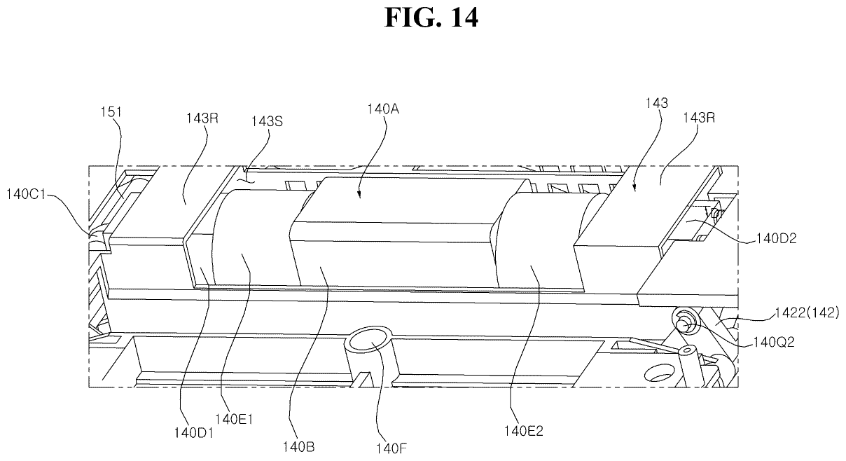

Referring next to FIG. 14, the cover 143 can cover the rear of the actuator 140A and can be coupled to the frame 140. As shown, the actuator 140A can be positioned in the internal space 143S of the cover 143. Also, the rear part 143R of the cover 143 can form the rear surface of the cover 143, and can form the rear boundary of the internal space 143S. The rear part 143R can be adjacent to the rear surface of the actuator 140A but spaced apart from it. The distance Dr between the rear surface of the actuator 140A and the front surface of the rear part 143R can vary depending on the height change of the actuator 140A with respect to the frame 140, and the minimum value of the distance Dr can be greater than 0. Accordingly, the actuator 140A that is raised in a rearward direction from the frame 140 or is lowered toward the frame 140 is not interfered with by the cover 143.

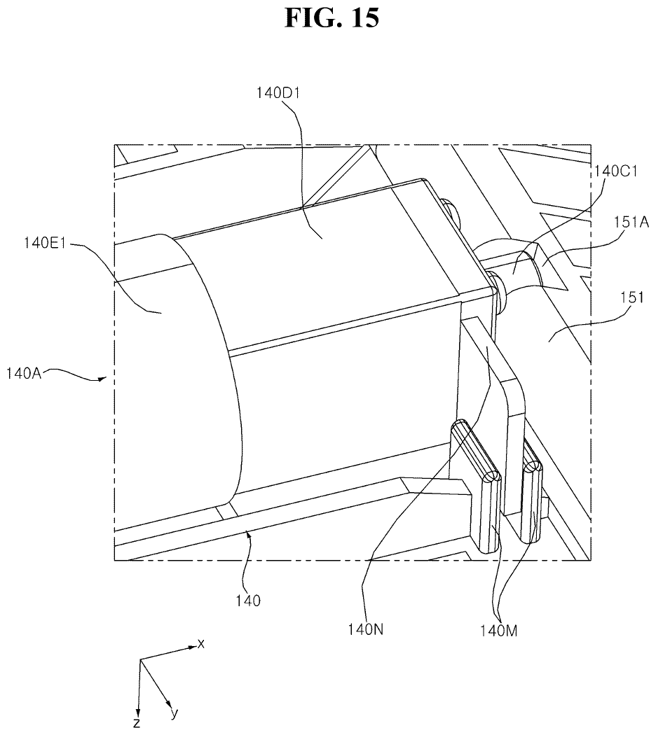

Referring to FIG. 15, a pair of ribs 140M can protrude from the rear surface of the frame 140, and can be adjacent to the first housing 140D1. In particular, the pair of ribs 140M can be spaced apart from each other in the movement direction of the first rod 140C1. A flange 140N can also protrude from the side surface of the first housing 140D1, and can be inserted into between the pair of ribs 140M.

Accordingly, in the movement direction of the first rod 140C1, i.e., in the horizontal direction, the movement of the actuator 140A can be restricted as the flange 140N is engaged with the ribs 140M. In addition, in the front-rear direction, the ribs 140M can guide the rising or falling of the actuator 140A with respect to the frame 140.

Referring again to FIG. 11, a sensor S can also be coupled to the rear of the frame 140. In particular, the sensor S can be coupled to the inside of the cover 143 (see FIG. 14). A first sensor S1 can be adjacent to the first link 141. The first sensor S1 can be spaced in a rearward direction from the rear surface of the frame 140 by a certain distance. Also, a second sensor S2 can be adjacent to the second link 142 and closer to the rear surface of the frame 140 than the first sensor S1.

For example, the sensor S can be a photo sensor and have a horseshoe shape. The sensor S can include a light emitting portion Sa and a light receiving portion Sb that are spaced apart from each other. In more detail, the light emitting portion Sa can output light in an infrared wavelength range toward the light receiving portion Sb, and the light receiving portion Sb can detect the light from the light emitting portion Sa. If an object exists between the light emitting portion Sa and the light receiving portion Sb, the light from the light emitting portion Sa may not reach the light receiving portion Sb, so that the sensor S can detect the object.

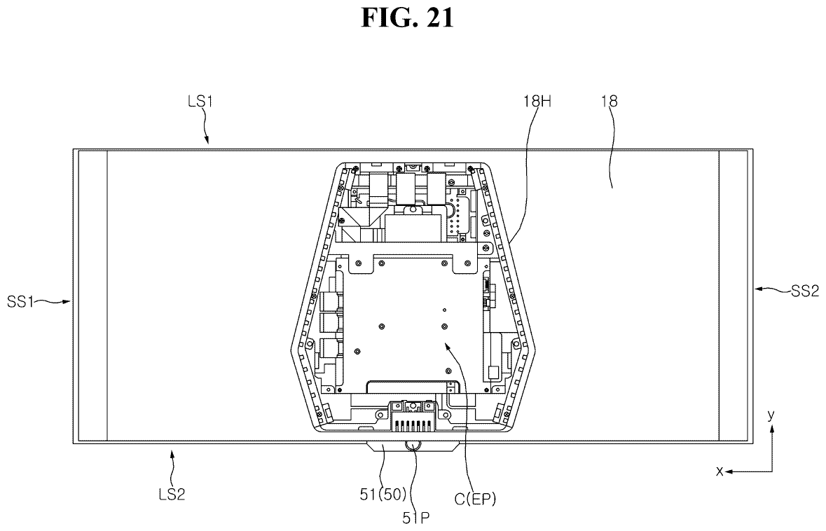

Also, a first protrusion 1413 can protrude from at least one of the first wings 1411, 1412 of the first link 141 and extend in a direction intersecting with the first wing 1411. In response to the rotation of the first link 141, the first protrusion 1413 can draw a circular trajectory, and the circular trajectory can pass through a space between the light emitting portion Sa and the light receiving portion Sb of the first sensor S1. When the display panel 11 and the plate 12 are bent to the maximum curvature (see the solid line in FIG. 13), the first protrusion 1413 can be positioned between the light emitting portion Sa and the light receiving portion Sb, and the first sensor S1 can detect the first protrusion 1413. Accordingly, the first sensor S1 can detect whether the display panel 11 and the plate 12 are bent to the maximum curvature. When the display panel 11 and the plate 12 are bent to the maximum curvature (see the solid line in FIG. 13), a control unit C (see FIG. 21) electrically connected to the first sensor S1 through a first cable Ca can stop the operation of the actuator 140A that is operated to bend the display panel 11 and the plate 12.

Also, a second protrusion 1423 can protrude from at least one of the second wings 1421, 1422 of the second link 142 and extend in a direction intersecting with the second wing 1421. In response to the rotation of the second link 142, the second protrusion 1423 can draw a circular trajectory, and the circular trajectory can pass through a space between the light emitting portion Sa and the light receiving portion Sb of the second sensor S2. When the display panel 11 and the plate 12 are flattened (see the dotted line in FIG. 13), the second protrusion 1423 can be positioned between the light emitting portion Sa and the light receiving portion Sb, and the second sensor S2 can detect the second protrusion 1423. Accordingly, the second sensor S2 can detect whether the display panel 11 and the plate 12 are flattened. When the display panel 11 and the plate 12 are flattened (see the dotted line in FIG. 13), the control unit C (see FIG. 21) electrically connected to the second sensor S2 through a second cable Cb can stop the operation of the actuator 140A that is operated to flatten the display panel 11 and the plate 12.

For example, a first angle between the first protrusion 1413 and the first wing 1411 can be the same as a second angle between the second protrusion 1423 and the second wing 1421. Meanwhile, in addition to the first sensor S1 and the second sensor S2, a third sensor S3 can be positioned in the first link 141 or the second link 142. The third sensor S3 can be positioned closer to the rear surface of the frame 140 than the first sensor S1, but positioned further from the rear surface of the frame 140 than the second sensor S2. In this case, a third protrusion 1414, 1424 can extend from the first wing 1412 or the second wing 1422, and the third sensor S3 can detect the third protrusion 1414, 1424. For example, a third angle between the third protrusion 1414, 1424 and the wing 1412, 1422 can be equal to the first angle. Accordingly, the third sensor S3 can detect whether the display panel 11 and the plate 12 are bent at a specific curvature that is less than the maximum curvature.

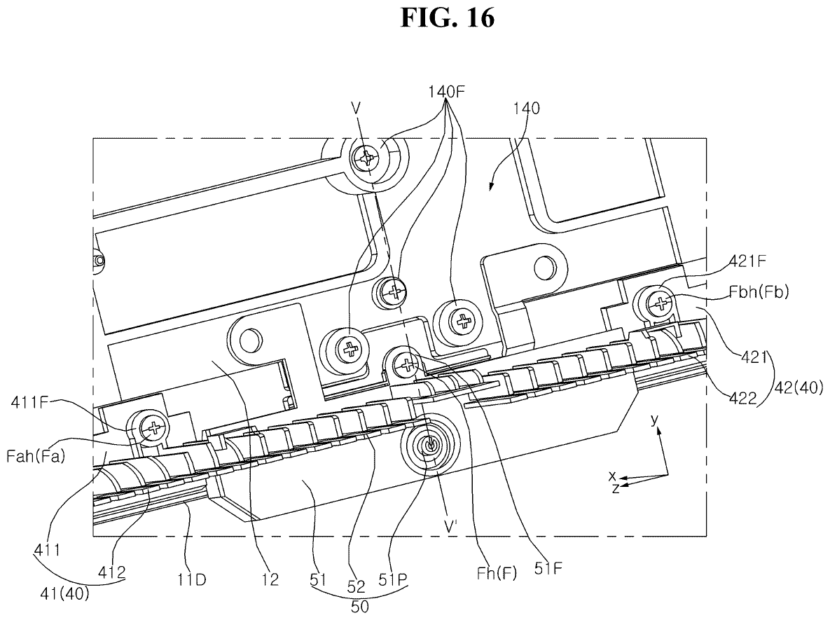

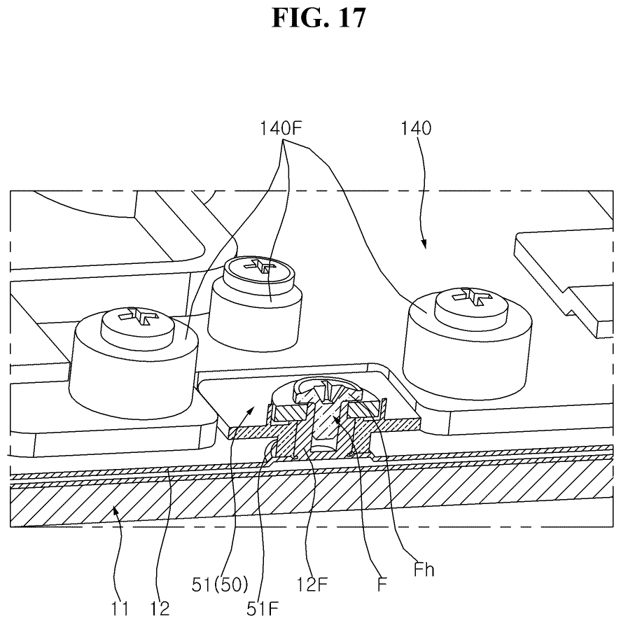

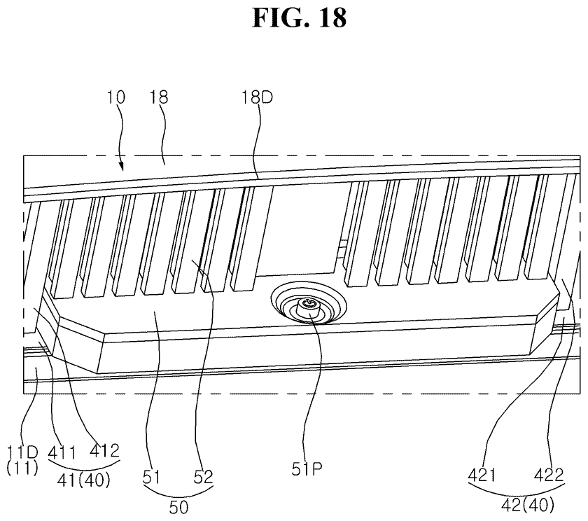

Referring to FIGS. 16 to 18, a controller 50 can be adjacent to the lower side 11D of the display panel 11. The controller 50 can be arranged in the central portion of the lower side 11D. The controller 50 can include a housing 51 and fins 52. The housing 51 can be positioned at the rear of the display panel 11. The housing 51 can be extended horizontally. The housing 51 can protrude downward from the lower side 11D of the display panel 11. A fixing portion 51F can protrude from the upper side of the housing 51. A fixing pin 12F can protrude from the rear surface of the plate 12, and can be inserted into the fixing portion 51F. The fixing pin 12F can be positioned in the vertical line VV′. The outer diameter of the fixing pin 12F can be substantially the same as the diameter of the hole of the fixing portion 51F into which the fixing pin 12F is inserted. A fastening member F such as a screw can be fastened to the fixing pin 12F, and the rear surface of the fixing portion 51F can be engaged with the head Fh of the fastening member F. Accordingly, the housing 51 can be fixed to the plate 12.

Also, a button 51P can be mounted on the rear surface of the housing 51. A user can press the button 51P to turn on the display 10. For example, the button 51P can be a joystick, and a user can control the display 10 by operating the button 51P. An antenna can also be mounted in the internal space of the housing 51.

In addition, the fins 52 can protrude from the rear surface of the housing 51. The fins 52 can be arranged in the length direction (i.e., left-right direction) of the housing 51 and be spaced apart from each other. A vent hole can also be formed between the fins 52.

Referring again to FIG. 16, a bottom grille 40 can be arranged along the lower side 11D of the display panel 11 and be referred to as a bottom vent member 40. The bottom grille 40 can include a first bottom grille 41 and a second bottom grille 42. The controller 50 can be arranged between the first bottom grille 41 and the second bottom grille 42. The bottom grille 40 can be referred to as a second grille 40. The second grille 40 can be flexible.

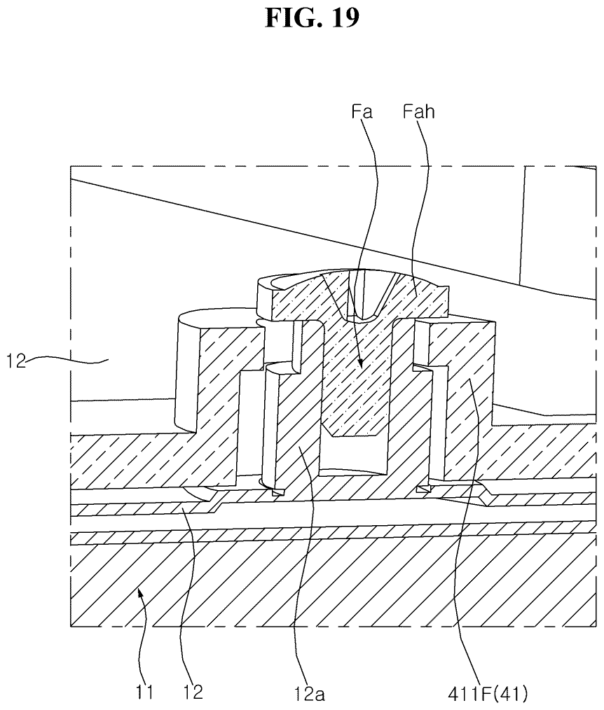

Referring to FIG. 19 together with FIG. 16, the first bottom grille 41 can be positioned at the rear of the display panel 11. The first bottom grille 41 can extend along the lower side 11D of the display panel 11. The first bottom grille 41 can include a body 411 and fins 412.

In addition, the body 411 can be adjacent to the lower side 11D of the display panel 11 and can extend along the lower side 11D. Also, a coupling pin 12a can protrude from the rear surface of the plate 12, and can be inserted into a coupling portion 411F of the body 411. The coupling pin 12a can be spaced to the left from the vertical line VV′. The outer diameter of the coupling pin 12a can be smaller than the diameter of the hole 411Fh of the coupling portion 411F into which the coupling pin 12a is inserted. A fastening member Fa such as a screw can be fastened to the coupling pin 12a, and the rear surface of the coupling portion 411F can be engaged with the head Fah of the fastening member Fa.

Accordingly, the body 411 can be coupled to the rear of the plate 12. If the plate 12 is flat (see the dotted line in FIG. 13), the coupling pin 12a can be positioned biased to the right of the central portion of the hole 411Fh. As the plate 12 is bent see (solid line in FIG. 13), the coupling pin 12a can be moved to the left within the hole 411Fh. That is, in response to the change in curvature of the plate 12, the plate 12 can slip with respect to the body 411.

In addition, the pins 412 can protrude from the rear surface of the body 411. Also, the pins 412 can be arranged in the length direction (i.e., left-right direction) of the body 411 and can be spaced apart from each other. A vent hole can also be formed between the pins 412.

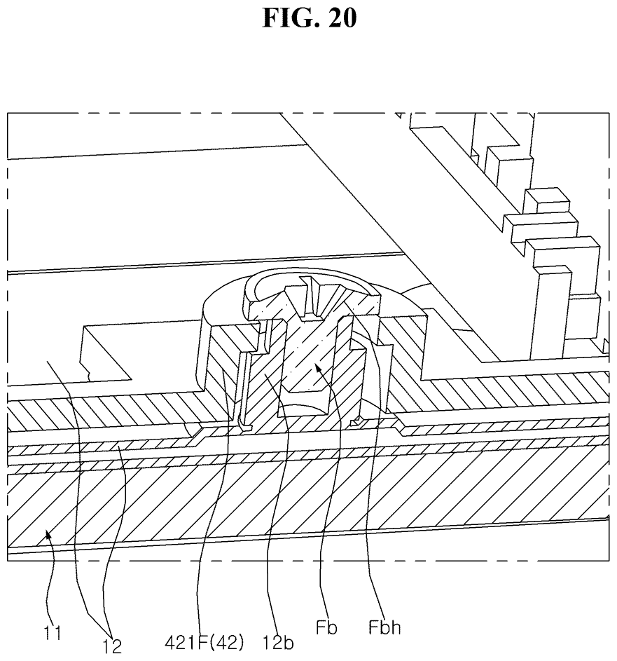

Referring to FIG. 20 together with FIG. 16, the second bottom grille 42 can be positioned at the rear of the display panel 11. In particular, the second bottom grille 42 can extend along the lower side 11D of the display panel 11 and include a body 421 and fins 422. In addition, the body 421 can be adjacent to the lower side 11D of the display panel 11 and can extend along the lower side 11D. Also, a coupling pin 12b can protrude from the rear surface of the plate 12, and can be inserted into a coupling portion 421F of the body 421. The coupling pin 12b can also be spaced to the right from the vertical line VV′. Further, the outer diameter of the coupling pin 12b can be smaller than the diameter of the hole 421Fh of the coupling portion 421F into which the coupling pin 12b is inserted. A fastening member Fb, such as a screw, can also be fastened to the coupling pin 12b, and the rear surface of the coupling portion 421F can be engaged with the head Fbh of the fastening member Fb.

Accordingly, the body 421 can be coupled to the rear of the plate 12. If the plate 12 is flat (see the dotted line in FIG. 13), the coupling pin 12b can be positioned biased to the left of the central portion of the hole 421Fh. As the plate 12 is bent (see the solid line in FIG. 13), the coupling pin 12b can move to the right within the hole 421Fh. That is, in response to the change in curvature of the plate 12, the plate 12 can slip with respect to the body 421.

In addition, the fins 422 can protrude from the rear surface of the body 421. In particular, the fins 422 can be arranged in the length direction (i.e., left-right direction) of the body 421 and spaced apart from each other. A vent hole can also be formed between the fins 422.

Referring again to FIG. 1, a top grille 30 can be arranged along the upper side of the display panel 11. In particular, the top grille 30 can be adjacent to the upper side of the display panel 11 and coupled to the rear of the plate 12 (see FIG. 13). The top grille 30 can be opposite to a bottom grille 40 (see FIG. 16 and can be referred to as a top vent member 30. The top grille 30 can also have a shape identical to or corresponding to that of the bottom grille 40. Fins 32 of the top grille 30 can intersect with the display panel 11, and can be arranged along the upper side of the display panel 11. A vent hole can be formed between the fins 32. The top grille 30 can be referred to as a first grille 30. The first grille 30 can be flexible.

Accordingly, the internal space of the display 10 can be communicated with the outside of the display 10 through a gap between the fins 32 of the top grille 30, a gap (see FIG. 16) between the fins 412, 422 of the bottom grille 40, and a gap (see FIG. 16) between the fins 52 of the controller 50. The heat of the display 10 can be dissipated to the outside by air passing through the gaps.

In addition, the fins 32, 412, 422, 52 can form a parabolic curve convex toward the rear. The height at which the fins 32, 412, 422, 52 protrude in a rearward direction from the plate 12 (see FIG. 3) can gradually decrease from the central portion of the fins 32, 412, 422, 52 to the outer edge of the fins 32, 412, 422, 52. Further, the upper side of a back cover 18 can extend along the fins 32, and the lower side of the back cover 18 can extend along the fins 412, 422, 52. The left side of the back cover 18 can extend in a straight line, and can be positioned on the first side frame 161 (see FIG. 13). Also, the right side of the back cover 18 can extend in a straight line, and can be positioned on the second side frame 162 (see FIG. 13).

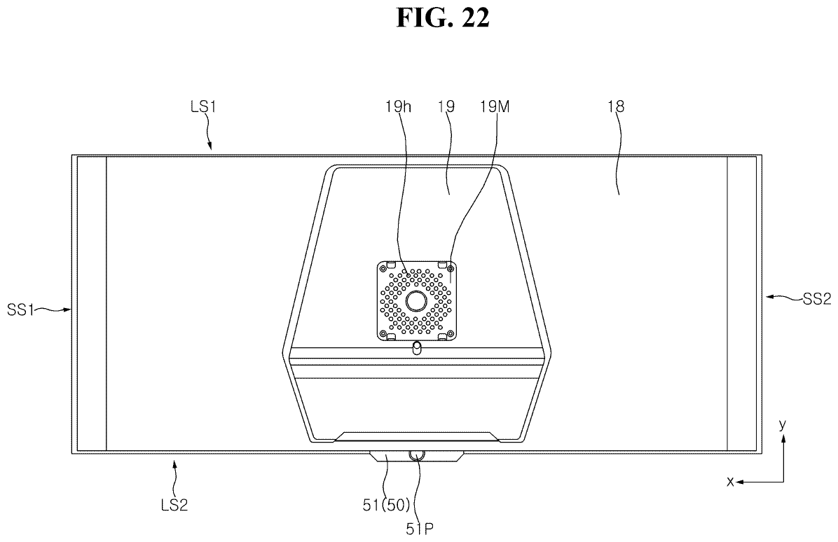

Referring to FIGS. 21 and 22, the back cover 18 can cover the rear of the plate 12 (see FIG. 3). The back cover 18 can cover components coupled to the rear of the plate 12, such as the driving module 14, the arms 151, 152, and the side frames 161, 162. Fins 32, 412, 422, 52 (see FIGS. 1 and 16) can be positioned between the plate 12 and the back cover 18. The back cover 18 can be curved along the fins 32, 412, 422, 52 (see FIG. 1). The back cover 18 can be flexible. The back cover 18 can be bent or flattened together with the display panel 11 and the plate 12.

Also, a hole 18H can be formed in the central portion of the back cover 18. For example, the hole 18H can have a hexagonal shape. Electronic components EP can be positioned inside the hole 18H, and can be coupled to the rear of the plate 12 (see FIG. 3).

In addition, a central cover 19 can cover the hole 18H, and can be coupled to the back cover 18. Holes 19h can also be formed in the central cover 19. Mount 19M can be formed in the central portion of the central cover 19, and can have the holes 19h. The column 4 (see FIG. 1) of the stand 2 can be mounted on the mount 19M.

Referring to FIGS. 1 to 22, the display device can include a flexible display panel; a flexible plate which is positioned at a rear of the display panel, and to which the display panel is coupled; a first side frame which is adjacent to a first side of the plate and which is coupled to a rear of the plate; a second side frame which is adjacent to a second side of the plate opposite to the first side of the plate and which is coupled to the rear of the plate; a first arm which extends in a direction intersecting with the first side of the plate, and which is rotatably coupled to the first side frame; a second arm which extends in a direction intersecting with the second side of the plate, and which is rotatably coupled to the second side frame; and a driving module which is positioned between the first arm and the second arm, and which rotates the first arm and the second arm.

Also, the driving module can include a frame which is coupled to the rear of the plate; an actuator which includes a first rod and a second rod that move in opposite directions, and which is positioned at a rear of the frame; a first link which connects the first arm to the frame, and which is rotatably coupled to the first arm and the frame; and a second link which connects the second arm to the frame, and which is rotatably coupled to the second arm and the frame, in which the first rod can push or can pull the first arm, in response to a driving of the actuator, and the second rod can push or can pull the second arm, in response to the driving of the actuator.

The driving module can further include a first front shaft penetrating the first link and the frame; and a first rear shaft penetrating the first link, the first arm, and the first rod. The first link can include: a first link base rotatably coupled to the frame; and a pair of first wings intersecting with the first link base. The first arm can include a first groove in which the first rod is positioned, can be positioned between the pair of first wings, and can be rotatably coupled to the first rod and the pair of first wings.

The pair of first wings can rotate with respect to the frame and can draw a circular trajectory. The actuator can move in a direction away from or toward the frame, in response to the driving of the actuator. The actuator can be positioned farthest in a rearward direction from the frame, when the display panel is bent at a specific curvature less than a maximum curvature. The driving module can further include: a pair of ribs which protrude from a rear surface of the frame, and which are spaced apart from each other in a direction of movement of the first rod; and a flange which protrudes from a side surface of the actuator, and which is inserted into between the pair of ribs.

The actuator can include a motor; a first reducer between the first rod and the motor; and a second reducer between the second rod and the motor. The display device can further include a sensor adjacent to the first wing of the first link. The first link can further include a first protrusion which protrudes from the first wing and which intersects with the first wing, and the sensor can detect the first protrusion. The sensor can include a light emitting portion and a light receiving portion which are spaced apart from each other, and when the first protrusion is positioned between the light emitting portion and the light receiving portion, the sensor can detect the first protrusion.

The first protrusion can be detected by the sensor, when the display panel is bent at a maximum curvature, or when the display panel is flat. The frame can be positioned on a vertical line passing through a center of the plate, and a point at which the frame is fixed to the plate can be positioned on the vertical line, or can be positioned less than a certain distance from the vertical line. The driving module can be symmetrical with respect to the vertical line. The display device can further include: a first shaft which penetrates the first side frame and the first arm, and which provides a rotation axis of the first arm; and a second shaft which penetrates the second side frame and the second arm, and which provides a rotation axis of the second arm.

The plate can be slidable with respect to the display panel. The display device can further include a first side pin which is adjacent to the first side frame and which protrudes in a rearward direction from the display panel. The plate can include a first rear slot into which the first side pin is movably inserted, and a rear surface of the plate can be engaged with a head of the first side pin.

The display device can further include a controller which is positioned on a vertical line passing through a center of the plate, and which is adjacent to a lower side of the plate, and which is coupled to the rear of the plate; a first bottom grille which is positioned between the first side of the plate and the controller, and which is slidable with respect to the plate; and a second bottom grille which is positioned between the second side of the plate and the controller, and which is slidable with respect to the plate, in which a portion of the controller can protrude downwardly from the lower side of the plate.

A display device can include a flexible display panel; a flexible plate which is positioned at a rear of the display panel, and to which the display panel is coupled; a driving module which is positioned at a rear of the plate; a first arm which includes one side rotatably coupled to the driving module, and which includes the other side that is adjacent to a first side of the plate and rotatably coupled to the plate; and a second arm which includes one side rotatably coupled to the driving module, and which includes the other side that is adjacent to a second side of the plate opposite to the first side of the plate and rotatably coupled to the plate.

A display device can include a flexible display panel; a flexible plate which is positioned at a rear of the display panel, and to which the display panel is coupled; a driving module which is positioned at a rear of the plate; a first arm which extends in a direction intersecting with a first side of the plate, and which receives power from the driving module to push the first side in a forward direction or to pull the first side in a rearward direction; and a second arm which extends in a direction intersecting with a second side of the plate opposite to the first side of the plate, and which receives power from the driving module to push the second side in a forward direction or to pull the second side in a rearward direction.

The effects of the display device according to the present disclosure are described as follows.

According to at least one of the embodiments of the present disclosure, a structure that can freely change the curvature of a display panel can be provided. According to at least one of the embodiments of the present disclosure, a mechanism that can freely change the curvature of a display panel can be provided. According to at least one of the embodiments of the present disclosure, a structure for synchronizing the rotation of arms that bend or unfold a display panel can be provided.

According to at least one of the embodiments of the present disclosure, a structure for pushing or pulling arms while an actuator is lifted can be provided. According to at least one of the embodiments of the present disclosure, a structure for minimizing vibration and noise of an actuator can be provided. Certain embodiments or other embodiments of the invention described above are not mutually exclusive or distinct from each other. Any or all elements of the embodiments of the invention described above can be combined or combined with each other in configuration or function.

For example, a configuration “A” described in one embodiment of the invention and the drawings and a configuration “B” described in another embodiment of the invention and the drawings can be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

What is claimed is:

1. A display device comprising:
a flexible plate
a flexible display panel coupled to the flexible plate;
a first side frame coupled to a rear first side of the flexible plate;
a second side frame coupled to a rear second side of the flexible plate;
a center frame coupled to the flexible plate between the first side frame and the second side frame;
a first arm extending from the center frame to the first side frame, and rotatably coupled to the first side frame;
a second arm extending from the center frame and the second side frame, and rotatably coupled to the second side frame; and
a driving module on the center frame and configured to actuate slidable and moveable first and second rods in and out to slidably extend and retract the first arm and the second arm, respectively.

2. The display device of claim 1, wherein the driving module includes:
an actuator including the first rod and the second rod that move in opposite directions to extend and retract the first arm and the second arm;
a first link connecting the first arm to the center frame, and rotatably coupled to the first arm and the center frame; and
a second link connecting the second arm to the center frame, and rotatably coupled to the second arm and the center frame, and
wherein the first link and the second link are rotatable away from the center frame in response to the driving module slidably retracting the first and second arms and flexibly curving the flexible plate, and the first link and the second link are rotatable toward the center frame to slidably extend the first and second arms and uncurve the flexible plate.

3. The display device of claim 2, wherein the driving module further comprises:
a first front shaft penetrating the first link and the center frame; and
a first rear shaft penetrating the first link, the first arm, and the first rod.

4. The display device of claim 2, wherein the first link comprises:
a first link base rotatably coupled to the center frame; and
a pair of first wings intersecting with the first link base, and
wherein the first arm comprises a first groove receiving the first rod, and positioned between the pair of first wings, and is rotatably coupled to the first rod and the pair of first wings to extend and retract the first arm and the second arm.

5. The display device of claim 4, wherein the pair of first wings rotate with respect to the center frame and draw a circular trajectory.

6. The display device of claim 5, wherein the actuator moves the first rod and the second rod in a direction away from or toward the first side frame and the second side frame, respectively, in response to a driving of the actuator.

7. The display device of claim 6, wherein the actuator is positioned farthest in a rearward direction from the center frame, when the flexible display panel is bent at a specific curvature less than a maximum curvature.

8. The display device of claim 6, wherein the driving module further comprises:
a pair of ribs protruding from a rear surface of the center frame, and spaced apart from each other in a direction of movement of the first rod; and
a flange protruding from a side surface of the actuator, and inserted into between the pair of ribs.

9. The display device of claim 2, wherein the actuator comprises:
a motor;
a first reducer between the first rod and the motor; and
a second reducer between the second rod and the motor.

10. The display device of claim 4, further comprising:
a sensor adjacent to the first wing of the first link,
wherein the first link further comprises a first protrusion protruding from the first wing and intersecting with the first wing, and
wherein the sensor detects the first protrusion.

11. The display device of claim 10, wherein the sensor comprises a light emitting portion and a light receiving portion spaced apart from each other, and
wherein, when the first protrusion is positioned between the light emitting portion and the light receiving portion, the sensor detects the first protrusion.

12. The display device of claim 10, wherein the first protrusion is detected by the sensor, when the flexible display panel is bent at a maximum curvature, or when the flexible display panel is flat.

13. The display device of claim 2, wherein the center frame is positioned on a vertical line passing through a center of the flexible plate, and
wherein a point at which the center frame is fixed to the flexible plate is positioned on the vertical line, or is positioned less than a certain distance from the vertical line.

14. The display device of claim 13, wherein the driving module is symmetrical with respect to the vertical line.

15. The display device of claim 1, further comprising:
a first shaft penetrating the first side frame and the first arm, and providing a rotation axis of the first arm; and
a second shaft penetrating the second side frame and the second arm, and providing a rotation axis of the second arm.

16. The display device of claim 1, wherein the flexible plate is slidable with respect to the flexible display panel.

17. The display device of claim 16, further comprising a first side pin adjacent to the first side frame and protruding in a rearward direction from the flexible display panel,
wherein the flexible plate comprises a first rear slot into which the first side pin is movably inserted, and
wherein a rear surface of the flexible plate is engaged with a head of the first side pin.

18. The display device of claim 1, further comprising:
a controller positioned on a vertical line passing through a center of the flexible plate, and coupled to a rear of the flexible plate adjacent to a lower side of the flexible plate;
a first bottom grille positioned between the first side frame and the controller, and which is slidable with respect to the flexible plate; and
a second bottom grille positioned between the second side frame and the controller, and which is slidable with respect to the flexible plate,
wherein a portion of the controller protrudes downwardly from the lower side of the flexible plate.

19. The display device of claim 2, wherein the first link comprises first and second through holes for connection to the center frame and the first arm,
wherein the second link comprises first and second through holes for connection to the center frame and the second arm,
wherein the first link is connected to the center frame and the first arm via a first rotatable shaft inserted through the first through hole of the first link, and
wherein the second link is connected to the center frame and the first arm via a second rotatable shaft inserted through the first through hole of the second link.

20. The display device of claim 2, wherein the actuator is moveable disposed within the driving module.
